(19) United States
(12) Patent Application Publication
(10) Pub. No.: US 2013/0133741 A1
(43) Pub. Date: May 30, 2013

(54) PHOTOVOLTAIC DEVICE AND MANUFACTURING METHOD THEREOF

(71) Applicant: Satoshi Hamamoto, Tokyo (JP)

(72) Inventor: Satoshi Hamamoto, Tokyo (JP)

(73) Assignee: Mitsubishi Electric Corporation, Chiyoda-ku, Tokyo (JP)

(21) Appl. No.: 13/813,865

(22) PCT Filed: Oct. 5, 2010
(86) PCT No.: PCT/JP2010/067482

§ 371 Date: Feb. 1, 2013

(51) Int. Cl. H01L 31/0232; H01L 31/18

(52) U.S. Cl. CPC H01L 31/02327; H01L 31/18
USPC 136/256; 438/72

(57) ABSTRACT

In a photovoltaic device, a second electrode includes an Al-based electrode that is connected to an other surface side of a substrate by being embedded in openings on the other surface side of the substrate, and an Ag-based electrode that is provided in a region between the openings on the other surface side of the substrate and is electrically connected to the other surface side of the substrate by at least a part thereof penetrating a back surface insulating film, and a sum of an area of the Ag-based electrode in a plane of the substrate and an area of a peripheral region, which is obtained by extending a pattern of the Ag-based electrode by a diffusion length of a carrier outward in a plane of the substrate, is 10% or less of an area on the other surface side of the substrate.

### FIELD

The present invention relates to a photovoltaic device and a manufacturing method thereof.

### BACKGROUND

In recent photovoltaic devices, materials and manufacturing processes have been improved so that the devices can output high power. Therefore, in order to output higher power, it is important to realize a structure or a manufacturing process that causes light in a wavelength range that conventionally cannot be sufficiently utilized to contribute to power generation by optical confinement within a photovoltaic device or suppression of the recombination velocity of carriers in the front surface and back surface. Thus, improvement of the back surface structure of a substrate that plays a role therein is very important.

In order to reflect light from the back surface side of the substrate or suppress the recombination velocity in the vicinity of back surface of the substrate, for example, a technology has been proposed in which after a back surface electrode is locally printed and fired, a film that suppresses the recombination velocity is formed (for example, see Patent Literature 1). In addition, for example, a technology has been proposed in which after a film that suppresses the recombination velocity is formed on the back surface of the substrate, openings are formed in part thereof and, moreover, back surface electrode paste is printed and fired over the entire surface (for example, see Patent Literature 2).

### CITATION LIST

### Patent Literature

Patent Literature 1: Japanese Patent Application Laid-open No. H06-169096
Patent Literature 2: Japanese Patent Application Laid-open No. 2002-246625

### SUMMARY

### Technical Problem

However, in the method in the above Patent Literature 1, the film that suppresses the recombination velocity is formed after the back surface electrode is printed and fired. In this case, particularly, when firing is performed, the adhesion or fixation of contaminants to the back surface of the substrate proceeds, therefore, there is a problem in that it is extremely difficult to keep the recombination velocity of carriers in the vicinity of back surface of the substrate low as intended.

Moreover, in the method in the above Patent Literature 2, the back surface electrode, which also has a light reflecting function, is formed by printing the electrode paste to cover almost the entire surface of the film that suppresses the recombination velocity, therefore, the back surface electrode is partially in contact with the back surface of the substrate. However, if the back surface electrode consists of, for example, paste containing aluminum (Al), which is a typical material, the optical reflectance of the back surface cannot be increased, therefore, a sufficient optical confinement effect within a photovoltaic device cannot be obtained. Moreover, if the back surface electrode consists of, for example, paste containing silver (Ag), which is a typical material, when a firing process of the electrode is performed, the film that suppresses the recombination velocity is also corroded in regions other than the original contact portions due to the fire through, therefore, a sufficient suppression effect of the recombination velocity of carriers cannot be obtained.

On the other hand, when solar cells are configured into a solar cell module, a plurality of solar cells is connected in series or both in series and in parallel via metal tabs. Typically, a connecting electrode on the cell side is formed by the fire through using metal paste containing silver. Both the electrical connection and the physical adhesion strength can be obtained between the silicon substrate and the electrode by using the fire through.

However, at the interface between the silver electrode and the silicon, the recombination velocity is extremely large, therefore, formation of the electrode by the fire through is problematic in the back surface of the silicon solar cell. In other words, the open circuit voltage (Voc) and the photoelectric conversion efficiency decrease in some cases by electrically connecting the back surface silver electrode and the silicon crystal of the silicon substrate in the back surface structure of the silicon solar cell.

The present invention is achieved in view of the above and has an object to obtain a photovoltaic device that has a low recombination velocity and a high back surface reflectance and is excellent in photoelectric conversion efficiency and a manufacturing method thereof.

### Solution to Problem

There is provided a photovoltaic device comprising: a first conductivity-type semiconductor substrate that includes an impurity diffusion layer in which a second conductivity-type impurity element is diffused on one surface side; an anti-reflective film formed on the impurity diffusion layer; a first electrode that penetrates the anti-reflective film and is electrically connected to the impurity diffusion layer; a back surface insulating film that includes a plurality of openings that reach an other surface side of the semiconductor substrate and is formed on the other surface side of the semiconductor substrate; a second electrode that is formed on the other surface side of the semiconductor substrate; and a back surface reflective film that is made of a metal film formed by a vapor phase growth method or is configured to include a metal foil, and is formed to cover at least the back surface insulating film, wherein the second electrode includes an aluminum-based electrode that is made of a material including aluminum and is connected to the other surface side of the semiconductor substrate by being embedded in at least the openings on the other surface side of the semiconductor substrate, and a silver-based electrode that is made of a material including silver, that is provided in a region between the openings on the other surface side of the semiconductor substrate, that is electrically connected to the other surface side of the semiconductor substrate by at least a part thereof penetrating the back surface insulating film, and that is electrically connected to the aluminum-based electrode via the back surface reflective film, and a sum of an area of the silver-based electrode in a plane of the semiconductor substrate and an area of a peripheral region, which is obtained by extending a pattern of the silver-based electrode by a diffusion length of a carrier in the semiconductor substrate outward in a plane of the semiconductor substrate, is 10% or less of an area on the other surface side of the semiconductor substrate.

### Advantageous Effects of Invention

According to the present invention, an effect is obtained where a solar cell, which has a back surface structure having both a low recombination velocity and a high back surface reflectance and in which the photoelectric conversion efficiency is improved, can be obtained. Then, according to the present invention, an effect is obtained where a decrease in the open circuit voltage (Voc) and the photoelectric conversion efficiency due to the electrical connection between the back surface silver electrode and the semiconductor substrate can be prevented.

### BRIEF DESCRIPTION OF DRAWINGS

FIG. 1-1 is a cross-sectional view of a main portion for explaining a cross-sectional structure of a solar cell according to a first embodiment of the present invention.

FIG. 1-2 is a top view of the solar cell according to the first embodiment of the present invention when viewed from a light receiving surface side.

FIG. 1-3 is a bottom view of the solar cell according to the first embodiment of the present invention when viewed from a back surface side.

FIG. 2 is a characteristic diagram illustrating a reflectance of the back surface of a semiconductor substrate in three kinds of samples having different back surface structures.

FIG. 3 is a characteristic diagram illustrating a relationship between the area ratio of back surface electrodes and the open circuit voltage (Voc) in samples manufactured to resemble the solar cell according to the first embodiment.

FIG. 4 is a characteristic diagram illustrating a relationship between the area ratio of the back surface electrodes and the short-circuit current density (Jsc) in samples manufactured to resemble the solar cell according to the first embodiment.

FIG. 5-1 is a cross-sectional view for explaining a manufacturing process of the solar cell according to the first embodiment of the present invention.

FIG. 5-2 is a cross-sectional view for explaining a manufacturing process of the solar cell according to the first embodiment of the present invention.

FIG. 5-3 is a cross-sectional view for explaining a manufacturing process of the solar cell according to the first embodiment of the present invention.

FIG. 5-4 is a cross-sectional view for explaining a manufacturing process of the solar cell according to the first embodiment of the present invention.

FIG. 5-5 is a cross-sectional view for explaining a manufacturing process of the solar cell according to the first embodiment of the present invention.

FIG. 5-6 is a cross-sectional view for explaining a manufacturing process of the solar cell according to the first embodiment of the present invention.

FIG. 5-7 is a cross-sectional view for explaining a manufacturing process of the solar cell according to the first embodiment of the present invention.

FIG. 5-8 is a cross-sectional view for explaining a manufacturing process of the solar cell according to the first embodiment of the present invention.

FIG. 5-9 is a cross-sectional view for explaining a manufacturing process of the solar cell according to the first embodiment of the present invention.

FIG. 6-1 is a plan view illustrating an example of the printed region of a back-surface-aluminum-electrode material paste on a back surface insulating film of the solar cell according to the first embodiment of the present invention.

FIG. 6-2 is a plan view illustrating an example of the printed region of the back-surface-aluminum-electrode material paste on the back surface insulating film of the solar cell according to the first embodiment of the present invention.

FIG. 7 is a cross-sectional view of a main portion for explaining a cross-sectional structure of a solar cell according to a second embodiment of the present invention.

FIG. 8-1 is a cross-sectional view of a main portion for explaining a cross-sectional structure of a solar cell according to a third embodiment of the present invention.

FIG. 8-2 is a top view of the solar cell according to the third embodiment of the present invention when viewed from a light receiving surface side.

FIG. 8-3 is a bottom view of the solar cell according to the third embodiment of the present invention when viewed from a back surface side.

FIG. 9 is a characteristic diagram illustrating the open circuit voltage of solar cells of a sample D to a sample F.

FIG. 10 is a diagram illustrating the electrode area ratio of back surface silver electrodes in the solar cells of the sample D to the sample F.

FIG. 11 is a plan view schematically illustrating the affected region by the back surface silver electrode according to the third embodiment of the present invention.

FIG. 12 is a characteristic diagram illustrating an example of a relationship between the ratio of the low open circuit voltage region in the back surface of a silicon substrate and the open circuit voltage.

### DESCRIPTION OF EMBODIMENTS

Embodiments of a photovoltaic device and a manufacturing method thereof according to the present invention will be explained below in detail with reference to the drawings. The present invention is not limited to the following descriptions and can be appropriately changed without departing from the scope of the present invention. Moreover, in the drawings illustrated below, the scale of each member is different from that in reality in some cases for ease of understanding. The same is also true between the drawings.

### First Embodiment

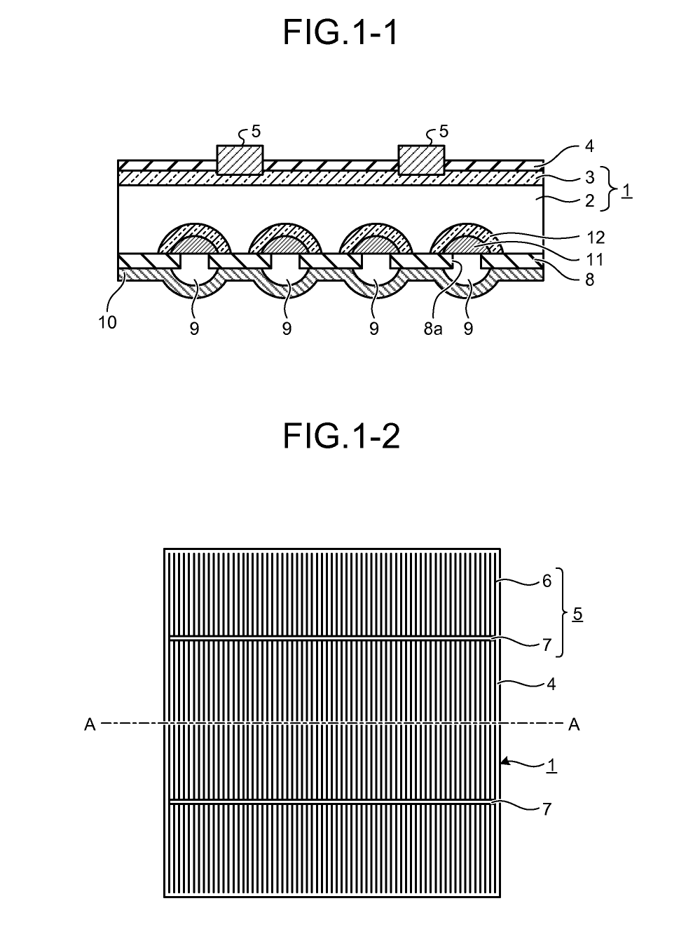

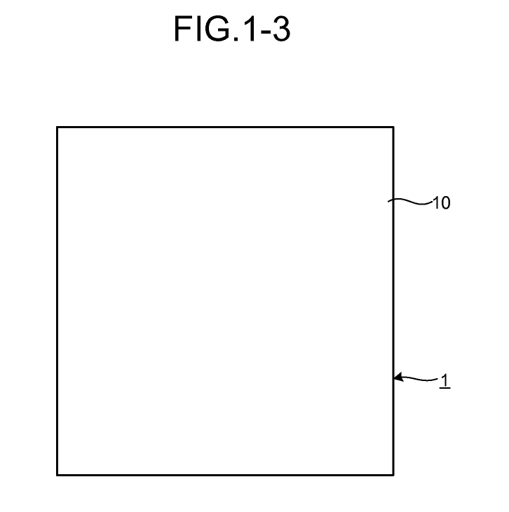

FIG. 1-1 to FIG. 1-3 are diagrams illustrating a configuration of a solar cell that is a photovoltaic device according to the present embodiment, in which FIG. 1-1 is a cross-sectional view of a main portion for explaining a cross-sectional structure of the solar cell, FIG. 1-2 is a top view of the solar cell when viewed from a light receiving surface side, and FIG. 1-3 is a bottom view of the solar cell when viewed from the opposite side (back surface side) of the light receiving surface side. FIG. 1-1 is a cross-sectional view of a main portion taken along line A-A in FIG. 1-2.

As shown in FIG. 1-1 to FIG. 1-3, the solar cell according to the present embodiment includes a semiconductor substrate 1 that is a solar cell substrate having a photoelectric conversion function and has a p-n junction, an anti-reflective film 4 that is formed on the surface (front surface) on the light receiving surface side of the semiconductor substrate 1 and consists of a silicon nitride film (SiN film), which is an insulating film that prevents the incident light from being reflected from the light receiving surface, a light-receiving-surface-side electrode 5 that is a first electrode formed to be surrounded by the anti-reflective film 4 on the surface (front surface) on the light receiving surface side of the semiconductor substrate 1, a back surface insulating film 8 that is formed on the surface (back surface) on the side opposite to the light receiving surface of the semiconductor substrate 1 and consists of a silicon nitride film (SiN film), back surface aluminum electrodes 9 that are a second electrode formed to be surrounded by the back surface insulating film 8 on the back surface of the semiconductor substrate 1, and a back surface reflective film 10 provided to cover the back surface insulating film 8 and the back surface aluminum electrodes 9 on the back surface of the semiconductor substrate 1.

In the semiconductor substrate 1, a p-n junction is formed by a p-type polycrystalline silicon substrate 2 that is a first conductivity-type layer and an impurity diffusion layer (n-type impurity diffusion layer) 3 that is a second conductivity-type layer formed by diffusing phosphorus on the light receiving surface side of the semiconductor substrate 1. The n-type impurity diffusion layer 3 has a surface sheet resistance of 30 to 100Ω/.

The light-receiving-surface-side electrode 5 includes grid electrodes 6 and bus electrodes 7 of the solar cell and is electrically connected to the n-type impurity diffusion layer 3. The grid electrodes 6 are provided locally on the light receiving surface for collecting electricity generated in the semiconductor substrate 1. The bus electrodes 7 are provided substantially orthogonal to the grid electrodes 6 to extract electricity collected by the grid electrodes 6.

On the other hand, the back surface aluminum electrodes 9 are partially embedded in the back surface insulating film 8 provided over substantially the entire back surface of the semiconductor substrate 1. In other words, in the back surface insulating film 8, substantially circular dot-shaped openings 8a, which reach the back surface of the semiconductor substrate 1, are formed. Then, the back surface aluminum electrodes 9 made of an electrode material containing aluminum, glass, and the like are provided such that each of them fills the opening 8a and has the outer shape wider than the diameter of the opening 8a in the in-plane direction of the back surface insulating film 8.

The back surface insulating film 8 consists of a silicon nitride film (SiN film) and is formed over substantially the entire back surface of the semiconductor substrate 1 by the plasma CVD (Chemical Vapor Deposition) method. A silicon nitride film (SiN film) formed by the plasma CVD method is used as the back surface insulating film 8, therefore, an excellent suppression effect of the recombination velocity of carriers can be obtained in the back surface of the semiconductor substrate 1.

The back surface reflective film 10 is provided to cover the back surface aluminum electrodes 9 and the back surface insulating film 8 on the back surface of the semiconductor substrate 1. The light transmitted through the semiconductor substrate 1 and the back surface insulating film 8 can be reflected and returned to the semiconductor substrate 1 by including the back surface reflective film 10 that covers the back surface insulating film 8, whereby an excellent optical confinement effect can be obtained. Then, in the present embodiment, the back surface reflective film 10 consists of a silver (Ag) film (silver sputtering film) formed by the sputtering method, which is a metal film formed by the vapor phase growth method. Because the back surface reflective film 10 is not a film formed by the printing method using electrode paste but consists of a sputtering film, the back surface reflective film 10 can realize higher light reflection than a silver (Ag) film formed by the printing method, therefore, the light transmitted through the semiconductor substrate 1 and the back surface insulating film 8 can be reflected more efficiently and returned to the semiconductor substrate 1. Thus, the solar cell according to the present invention can obtain an excellent optical confinement effect by including the back surface reflective film 10 that consists of a silver sputtering film.

As a material of the back surface reflective film 10, it is preferable to use a metal material whose reflectance for the light having a wavelength of, for example, around 1100 nm is 90% or higher, preferably, 95% or higher. Consequently, it is possible to realize a solar cell that has a high long wavelength sensitivity and is excellent in optical confinement effect to the light in a long wavelength region. In other words, although it depends on the thickness of the semiconductor substrate 1, it is possible to realize a high generated current by efficiently introducing long wavelength light having a wavelength of 900 nm or longer, particularly, about 1000 nm to 1100 nm, into the semiconductor substrate 1, therefore, the output characteristics can be improved. As such a material, for example, aluminum (Al) can be used other than silver (Ag).

In the solar cell according to the present embodiment, as described above, the fine back surface aluminum electrodes 9 are formed on the back surface of the semiconductor substrate 1 and the back surface reflective film 10 is formed thereon. Therefore, on the back surface reflective film 10 illustrated in FIG. 1-3, fine irregularities due to the back surface aluminum electrodes 9 are actually formed, however, the fine irregularities are not described in FIG. 1-3.

Moreover, an aluminum-silicon (Al—Si) alloy portion 11 is formed in a region, which is on the back surface side of the semiconductor substrate 1 and is in contact with the back surface aluminum electrode 9, and is formed in a portion near the region. Furthermore, in the outer peripheral portion thereof, a BSF (Back Surface Field) layer 12, which is a high-concentration diffusion layer whose conductivity type is equal to that of the p-type polycrystalline silicon substrate 2, is formed to surround the aluminum-silicon (Al—Si) alloy portion 11.

In the solar cell configured as above, when the semiconductor substrate 1 is irradiated with sunlight from the light receiving surface side of the solar cell, holes and electrons are generated. The generated electrons move toward the n-type impurity diffusion layer 3 and the generated holes move toward the p-type polycrystalline silicon substrate 2 due to the electric field of the p-n junction portion (junction surface between the p-type polycrystalline silicon substrate 2 and the n-type impurity diffusion layer 3). Consequently, there is an excess of electrons in the n-type impurity diffusion layer 3 and there is an excess of holes in the p-type polycrystalline silicon substrate 2, thereby generating the photovoltaic power. This photovoltaic power is generated in a direction that forward biases the p-n junction, therefore, the light-receiving-surface-side electrode 5 connected to the n-type impurity diffusion layer 3 becomes a negative electrode and the back surface aluminum electrodes 9 connected to the p-type polycrystalline silicon substrate 2 become a positive electrode, whereby current flows to a not-shown external circuit.

FIG. 2 is a characteristic diagram illustrating the reflectance of the back surface of the semiconductor substrate in three kinds of samples having different back surface structures. FIG. 2 illustrates the relationship between the wavelength of the light incident on the samples and the reflectance. Each sample is manufactured to resemble the solar cell and the basic structure other than the back surface structure is similar to the solar cell according to the present embodiment. Details of the back surface structure of each sample are as follows.

(Sample A)

An aluminum (Al) paste electrode made of electrode paste containing aluminum (Al) is provided over the entire back surface of the semiconductor substrate (corresponding to a conventional typical structure).

(Sample B)

A back surface insulating film that consists of a silicon nitride film (SiN) is formed over the entire back surface of the semiconductor substrate and an aluminum (Al) paste electrode made of electrode paste containing aluminum (Al) is provided over the entire surface of the back surface insulating film (corresponding to the conventional technology (Patent Literature 2)).

(Sample C)

A back surface insulating film that consists of a silicon nitride film (SiN) is formed over substantially the entire back surface of the semiconductor substrate, an aluminum (Al) paste electrode made of electrode paste containing aluminum (Al) is locally included on the back surface of the semiconductor substrate, and a highly reflective film that consists of a silver sputtering film is provided over the entire surface of the back surface insulating film (corresponding to the solar cell according to the present embodiment).

Each sample has a different back surface structure, however, other structures of each sample are similar, therefore, it is possible to check the different in reflectance between “the silicon (semiconductor substrate) and the back surface structure”. In order to check the state of the back surface reflection, it is sufficient to compare the reflectance at the wavelength of around 1200 nm that is absorbed little by silicon. This is because the wavelength of 1100 nm or less is absorbed by silicon and already contributes to power generation, and is therefore not suitable for comparing the back surface reflection. The reflectance illustrated in FIG. 2 is strictly a component leaked to the surface of the semiconductor substrate again as a result of multiple reflections from the back surface.

As is apparent from FIG. 2, in the sample B corresponding to the conventional technology (Patent Literature 2), the reflectance is improved a little compared with the sample A corresponding to a conventional typical structure, however, the reflectance improvement effect is not sufficient. On the other hand, the sample C corresponding to the solar cell according to the present embodiment has a high reflectance compared with the sample A and the sample B and the high reflectance between “the silicon (semiconductor substrate) and the back surface structure” is recognized, therefore, it is found that the sample C is suitable for improving the efficiency on the basis of the optical confinement function in the back surface.

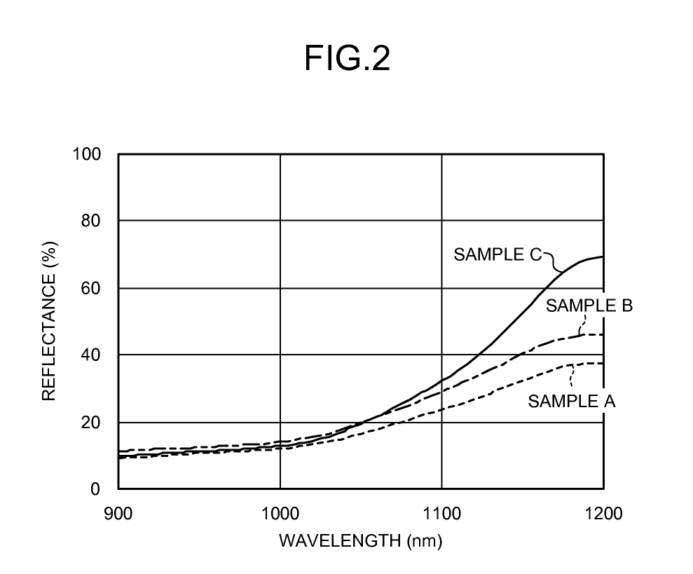

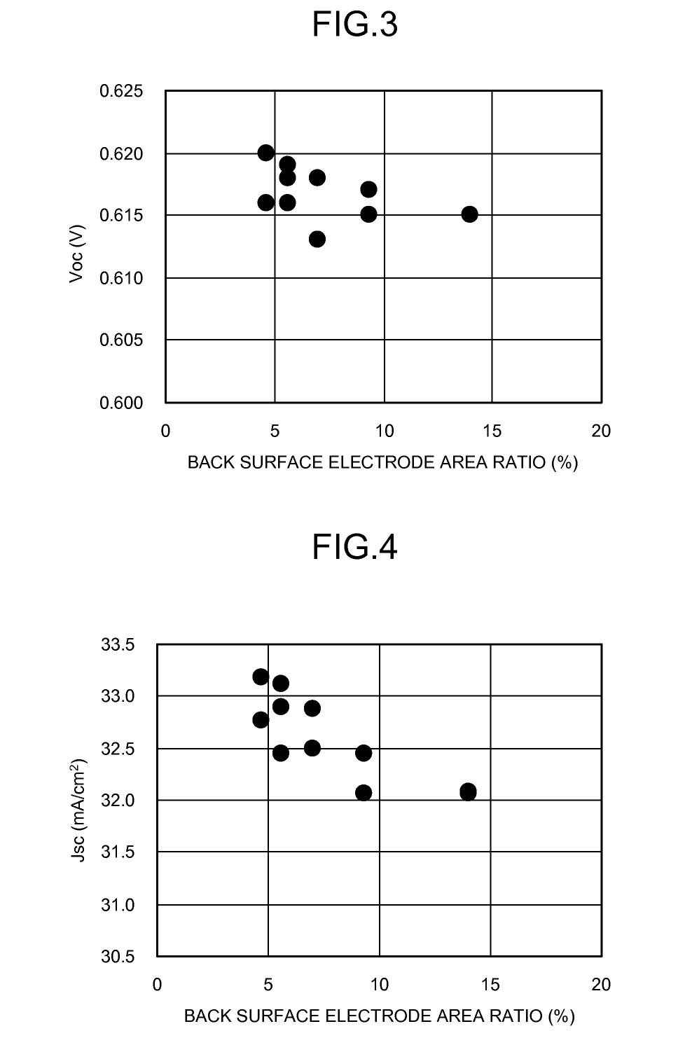

FIG. 3 is a characteristic diagram illustrating a relationship between the area ratio (ratio occupied by the back surface electrodes on the back surface of the semiconductor substrate) of the back surface electrodes and the open circuit voltage (Voc) in samples manufactured to resemble the solar cell according to the present embodiment in a similar manner to the above sample C. Moreover, FIG. 4 is a characteristic diagram illustrating a relationship between the area ratio (ratio occupied by the back surface electrodes on the back surface of the semiconductor substrate) of the back surface electrodes and the short-circuit current density (Jsc) in samples manufactured to resemble the solar cell according to the present embodiment in a similar manner to the above sample C.

As is apparent from FIG. 3 and FIG. 4, it can be recognized that as the area ratio of the aluminum (Al) paste electrodes that are the back surface electrodes decreases, i.e., as the area ratio of the highly reflective film according to the present embodiment increases, both the open circuit voltage (Voc) and the short-circuit current density (Jsc) improve and therefore an excellent suppression effect of the recombination velocity of carriers is obtained in the back surface of the semiconductor substrate. Consequently, it can be found that with the structure of the solar cell according to the present embodiment, it is possible to achieve both the improvement of the back surface reflection and the suppression of the recombination velocity of carriers in the back surface of the semiconductor substrate and the above effect can be obtained more significantly as the area ratio of the highly reflective film according to the present embodiment is increased.

In the solar cell according to the first embodiment configured as above, an excellent suppression effect of the recombination velocity of carriers can be obtained in the vicinity of back surface of the semiconductor substrate 1 by including the silicon nitride film (SiN film) formed on the back surface of the semiconductor substrate 1 by the plasma CVD method as the back surface insulating film 8. Consequently, in the solar cell according to the present embodiment, the output characteristics can be improved and therefore a high photoelectric conversion efficiency can be realized.

Moreover, in the solar cell according to the first embodiment, higher light reflection than a silver (Ag) film formed by a conventional printing method can be realized by including the back surface reflective film 10 that covers the back surface insulating film 8 and consists of a silver sputtering film, therefore, the light transmitted through the semiconductor substrate 1 and the back surface insulating film 8 can be reflected more efficiently and returned to the semiconductor substrate 1. Therefore, in the solar cell according to the present embodiment, an excellent optical confinement effect can be obtained. Thus, the output characteristics can be improved and therefore a high photoelectric conversion efficiency can be realized.

Accordingly, in the solar cell according to the first embodiment, a solar cell, which is excellent in long wavelength sensitivity and in which the photoelectric conversion efficiency is improved, can be realized by including a back surface structure that has both a low recombination velocity and a high back surface reflectance.

Next, an example of a manufacturing method of the solar cell as described above will be explained with reference to FIG. 5-1 to FIG. 5-9. FIG. 5-1 to FIG. 5-9 are cross-sectional views for explaining the manufacturing process of the solar cell according to the present embodiment.

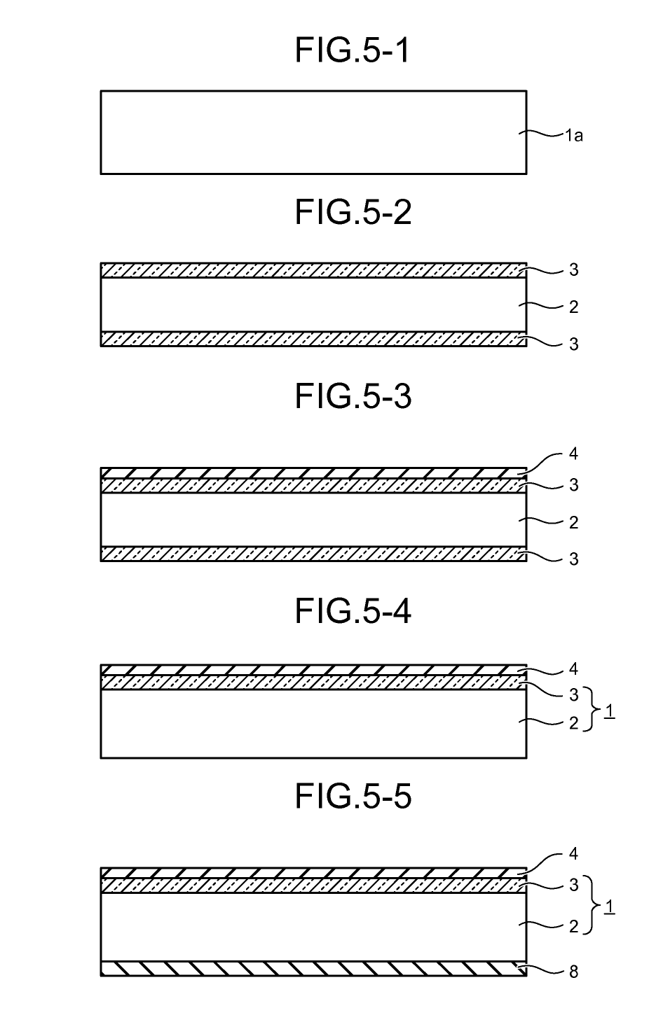

First, as the semiconductor substrate 1, for example, a p-type polycrystalline silicon substrate (hereinafter, referred to as a p-type polycrystalline silicon substrate 1a) most commonly used for a consumer solar cell is prepared (FIG. 5-1). As the p-type polycrystalline silicon substrate 1a, for example, a polycrystalline silicon substrate that contains a group III element, such as boron (B), and has an electrical resistance of about 0.5 to 3 Ωcm is used.

Because the p-type polycrystalline silicon substrate 1a is manufactured by slicing an ingot, which is obtained by cooling and solidifying molten silicon, by a wire saw, damage received when being sliced remains on the surface. Therefore, in order also to remove this damage layer, first, the surface is etched by immersing the p-type polycrystalline silicon substrate 1a into acid or heated alkaline solution, for example, aqueous sodium hydroxide, thereby removing the damaged area that is generated when the silicon substrate is cut and is present near the surface of the p-type polycrystalline silicon substrate 1a.

The thickness of the p-type polycrystalline silicon substrate 1a after the damage is removed is, for example, 200 μm and the size thereof is, for example, 150 mm×150 mm.

Moreover, at the same time as or subsequent to the removal of the damage, fine irregularities may be formed as a texture structure on the surface of the p-type polycrystalline silicon substrate la on the light receiving surface side. Formation of such a texture structure on the light receiving surface side of the semiconductor substrate 1 causes multiple reflections of light on the surface of the solar cell, therefore, the light incident on the solar cell can be efficiently absorbed in the p-type polycrystalline silicon substrate 1a. Consequently, the reflectance can be effectively reduced and thus the conversion efficiency can be improved.

The present invention is an invention related to the back surface structure of the photovoltaic device, therefore, the forming method and the shape of the texture structure are not particularly limited. For example, any of the following methods may be used: a method of using alkaline aqueous solution containing isopropyl alcohol or acid etching solution that mainly consists of a mixture of hydrofluoric acid and nitric acid; a method of forming a mask material, in which openings are partially formed, on the surface of the p-type polycrystalline silicon substrate 1a and obtaining a honeycomb structure or an inverted pyramid structure on the surface of the p-type polycrystalline silicon substrate 1a by performing etching via the mask material; a method of using a reactive gas etching (RIE: Reactive Ion Etching); and the like.

Next, the p-type polycrystalline silicon substrate 1a is introduced into a thermal diffusion furnace and is heated in an atmosphere of phosphorus (P) that is n-type impurity. With this process, the n-type impurity diffusion layer 3 is formed by diffusing phosphorus (P) into the surface of the p-type polycrystalline silicon substrate 1a, thereby forming a semiconductor p-n junction (FIG. 5-2). In the present embodiment, the n-type impurity diffusion layer 3 is formed by heating the p-type polycrystalline silicon substrate 1a in a phosphorus oxychloride (POCl₃) gas atmosphere, for example, at a temperature of 800° C. to 850° C. In the present embodiment, the heating process is controlled such that the surface sheet resistance of the n-type impurity diffusion layer 3 becomes, for example, 30 to 80Ω/, preferably, 40 to 60Ω/.

A phosphorus glass layer mainly made of oxide of phosphorus is formed on the surface of the n-type impurity diffusion layer 3 immediately after being formed, therefore, this is removed by using hydrofluoric acid solution or the like.

Next, in order to improve the photoelectric conversion efficiency, a silicon nitride film (SiN film) is formed as the anti-reflective film 4 on the light receiving surface side of the p-type polycrystalline silicon substrate 1a on which the n-type impurity diffusion layer 3 is formed (FIG. 5-3). For forming the anti-reflective film 4, a silicon nitride film is formed as the anti-reflective film 4, for example, by using a mixture of silane and ammonia by using the plasma CVD method. The film thickness and the refractive index of the anti-reflective film 4 are set to values that suppress light reflection the most. As the anti-reflective film 4, two or more layers of films having different refractive indexes may be laminated. Moreover, for forming the anti-reflective film 4, a different film forming method, such as the sputtering method, may be used. Moreover, as the anti-reflective film 4, a silicon oxide film may be formed.

Next, the n-type impurity diffusion layer 3 formed on the back surface of the p-type polycrystalline silicon substrate 1a by diffusing phosphorus (P) is removed. Consequently, the semiconductor substrate 1 is obtained, in which the p-n junction is formed by the p-type polycrystalline silicon substrate 2, which is a first conductivity-type layer, and the impurity diffusion layer (n-type impurity diffusion layer) 3, which is a second conductivity-type layer formed on the light receiving surface side of the semiconductor substrate 1 (FIG. 5-4).

The n-type impurity diffusion layer 3 formed on the back surface of the p-type polycrystalline silicon substrate 1a is removed, for example, by a single-sided etching device. Alternatively, it is possible to use a method of using the anti-reflective film 4 as a mask material and immersing the entire p-type polycrystalline silicon substrate 1a into etchant. As the etchant, liquid, which is obtained by heating alkaline aqueous solution, such as sodium hydroxide and potassium hydroxide, at a temperature between the ambient temperature and 95° C., preferably, between 50° C. and 70° C., is used. Moreover, as the etchant, a mixed aqueous solution of nitric acid and hydrofluoric acid may be used.

After the etching of removing the n-type impurity diffusion layer 3, in order to keep the recombination velocity low in the film formation to be described later, a silicon surface exposed to the back surface of the semiconductor substrate 1 is cleaned. The silicon surface is cleaned, for example, by performing a RCA cleaning or by using hydrofluoric acid aqueous solution of about 1% to 20%.

Next, the back surface insulating film 8 that consists of a silicon nitride film (SiN film) is formed on the back surface side of the semiconductor substrate 1 (FIG. 5-5). On the silicon surface exposed to the back surface side of the semiconductor substrate 1, the back surface insulating film 8 consisting of a silicon nitride film (SiN film) that has a refractive index of 1.9 to 2.2 and a thickness of 60 nm to 300 nm is formed by the plasma CVD. The back surface insulating film 8 that consists of a silicon nitride film can be definitely formed on the back surface side of the semiconductor substrate 1 by using the plasma CVD. The recombination velocity of carriers in the back surface of the semiconductor substrate 1 can be suppressed by forming the back surface insulating film 8 as above, and the recombination velocity of 100 cm/sec or lower can be obtained at the interface between the silicon (Si) and the silicon nitride film (SiN film) in the back surface of the semiconductor substrate 1. Consequently, a back surface interface sufficient for outputting higher power can be realized.

If the refractive index of the back surface insulating film 8 falls outside the range of 1.9 to 2.2, it is difficult to stabilize the film forming environment of the silicon nitride film (SiN film) and the film quality of the silicon nitride film (SiN film) degrades. As a result, the recombination velocity at the interface with the silicon (Si) also degrades. Moreover, if the thickness of the back surface insulating film 8 is smaller than 60 nm, the interface with the silicon (Si) is not stabilized and therefore the recombination velocity of carriers degrades. If the thickness of the back surface insulating film 8 is larger than 300 nm, there is no functional disadvantage, however, a long time is required for forming the film and thus the cost increases, which is not preferable in terms of productivity.

Moreover, the back surface insulating film 8 may have a laminated structure of two layers in which, for example, a silicon oxide film (silicon thermal oxide film: SiO₂ film) formed by thermal oxidation and a silicon nitride film (SiN film) are laminated. The silicon oxide film (SiO₂ film) in this case is not a native oxide formed on the back surface side of the semiconductor substrate 1 during the process and is, for example, a silicon oxide film (SiO₂ film) intentionally formed by thermal oxidation. With the use of such a silicon oxide film (SiO₂ film), it is possible to obtain the suppression effect of the recombination velocity of carriers in the back surface of the semiconductor substrate 1 more stably than a silicon nitride film (SiN film).

Moreover, the thickness of the silicon oxide film (SiO₂ film) intentionally formed by thermal oxidation is preferably set to about 10 nm to 50 nm. If the thickness of the silicon oxide film (SiO₂ film) formed by thermal oxidation is smaller than 10 nm, the interface with the silicon (Si) is not stabilized and thus the recombination velocity of carriers degrades. If the thickness of the silicon oxide film (SiO₂ film) formed by thermal oxidation is larger than 50 nm, there is no functional disadvantage, however, a long time is required for forming the film and thus the cost increases, which is not preferable in terms of productivity. Moreover, if the film forming process is performed at a high temperature for reducing the time, the quality of the crystalline silicon itself degrades, which results in shortening the lifetime.

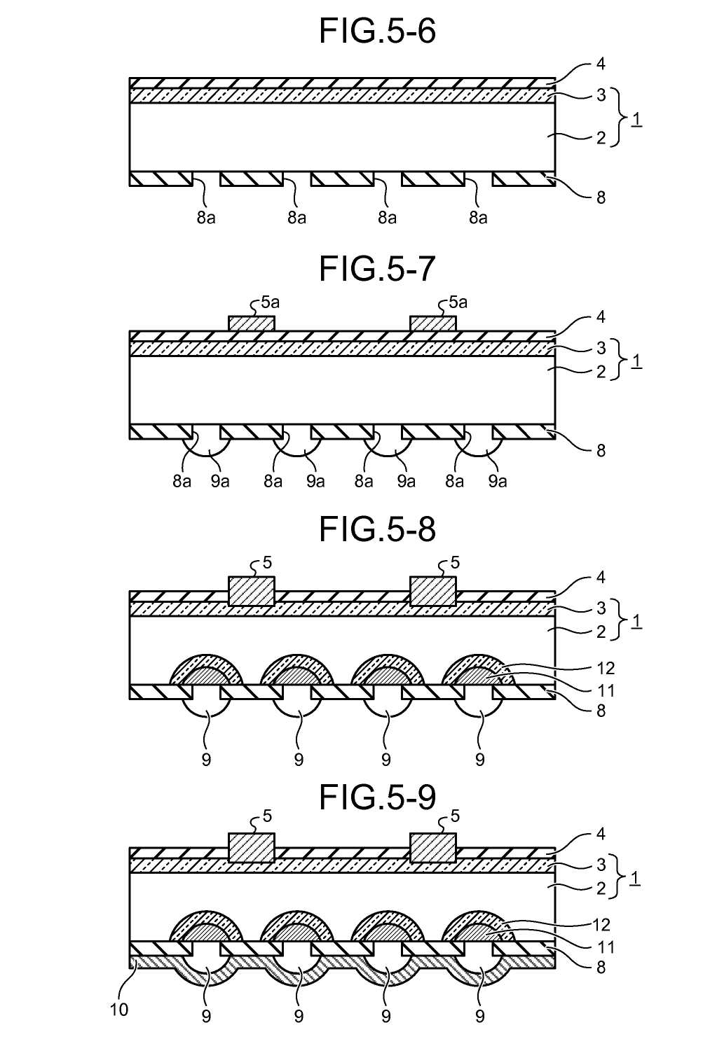

Thereafter, the dot-shaped openings 8a having predetermined intervals are formed in a part of or in the entire surface of the back surface insulating film 8 for forming contacts with the back surface side of the semiconductor substrate 1 (FIG. 5-6). The openings 8a are, for example, formed by directly patterning them in the back surface insulating film 8 by laser irradiation.

In order to form favorable contacts with the back surface side of the semiconductor substrate 1, it is preferable to increase the cross section of the openings 8a in the in-plane direction of the back surface insulating film 8 and increase the opening density of the openings 8a in the plane of the back surface insulating film 8. However, in order to obtain a high optical reflectance (back surface reflectance) on the back surface side of the semiconductor substrate 1, on the contrary, it is preferable that the cross section of the openings 8a be small and the opening density of the openings 8a be low. Therefore, the shape and the density of the openings 8a are preferably kept at the minimum level required for realizing favorable contacts.

Specifically, as the shape of the openings 8a, a substantially circular dot shape or a substantially rectangular shape, in which the diameter or the width is 20 μm to 200 μm and the interval between adjacent openings 8a is 0.5 mm to 2 mm, is exemplified. Moreover, as other shapes of the openings 8a, a stripe shape, in which the width is 20 μm to 200 μm and the interval between adjacent openings 8a is 0.5 mm to 3 mm, is exemplified. In the present embodiment, the dot-shaped openings 8a are formed by performing laser irradiation on the back surface insulating film 8.

Next, a back-surface-aluminum-electrode material paste 9a, which is an electrode material of the back surface aluminum electrodes 9 and contains aluminum, glass, and the like, is applied to a limited area by the screen printing method such that the openings 8a are filled, an area slightly larger than the diameter of the openings 8a in the in-plane direction of the back surface insulating film 8 is covered, and the back-surface-aluminum-electrode material paste 9a is not in contact with the back-surface-aluminum-electrode material paste 9a that fills the adjacent opening 8a, and the back-surface-aluminum-electrode material paste 9a is dried (FIG. 5-7). The application shape, the amount of application, and the like of the back-surface-aluminum-electrode material paste 9a can be changed according to various conditions, such as a diffusion concentration of aluminum in the Al—Si alloy portions 11 and the BSF layer 12 in the firing process to be described later.

It is required to ensure a sufficient amount of paste in the openings 8a and definitely form the Al—Si alloy portions 11 and the BSF layers 12 in the firing process. On the other hand, the optical reflectance (back surface reflectance) of the back surface aluminum electrodes 9 in the area in which the back surface insulating film 8 (silicon nitride film) and the back surface aluminum electrodes 9 are laminated on the back surface of the semiconductor substrate 1 is not sufficient. Therefore, if the formation area of the back surface aluminum electrodes 9 on the back surface insulating film 8 increases, the optical confinement effect within the photovoltaic device is reduced. Thus, the area in which the back-surface-aluminum-electrode material paste 9a is printed needs to be kept at the minimum required level while balancing the formation condition of the Al—Si alloy portions 11 and the BSF 12 with the optical confinement effect within the photovoltaic device.

In the present embodiment, the back-surface-aluminum-electrode material paste 9a containing aluminum (Al) is printed with a thickness of 20 μm such that the back-surface-aluminum-electrode material paste 9a overlaps the back surface insulating film 8 by the width of 20 μm from each end of the openings 8a. In this case, the back surface aluminum electrodes 9 to be formed can be prevented from being separated at the openings 8a of the back surface insulating film 8 by causing the back-surface-aluminum-electrode material paste 9a to overlap the back surface insulating film 8. FIG. 6-1 and FIG. 6-2 are plan views illustrating examples of the printed region of the back-surface-aluminum-electrode material paste 9a on the back surface insulating film 8. FIG. 6-1 illustrates an example where the opening 8a has a substantially circular dot shape and FIG. 6-2 illustrates an example where the opening 8a has a substantially rectangular shape.

It is desirable that the amount of overlap be controlled in the range of 200 μm² to 1000 μm², preferably, in the range of 400 μm² to 1000 μm² in the cross-sectional area from each end of the openings 8a. In the present embodiment, the paste thickness of the back-surface-aluminum-electrode material paste 9a containing aluminum (Al) is 20 μm², therefore, if this is expressed by the overlap width, this is equivalent to the range of 10 μm to 50 μm, preferably, the range of 20 μm to 50 μm from each end of the openings 8a. When the overlap width is less than 10 μm, the effect of preventing separation from the back surface insulating film 8 is not exhibited, and moreover, when firing is performed, i.e., when the alloy is formed, aluminum (Al) is not supplied appropriately and a portion is generated in which the BSF structure is not formed favorably. On the other hand, if the overlap width is more than 50 μm, the area ratio occupied by a portion in which the paste is printed increases, that is, the area ratio of the highly reflective film decreases, which largely departs from the intent of the invention.

When the opening 8a has a substantially circular dot shape as shown in FIG. 6-1, the back-surface-aluminum-electrode material paste 9a is applied to a limited area on the back surface insulating film 8 by the screen printing method in a substantially circular shape that includes a ring-shaped overlap region 9b having a width of 20 μm in the outer peripheral portion of the opening 8a on the back surface insulating film 8. For example, when the diameter d of the opening 8a is 200 μm, the back-surface-aluminum-electrode material paste 9a is printed in the shape of a substantially circular shape having a diameter of “200 μm+20 μm+20 μm=240 μm”.

Moreover, when the opening 8a has a substantially rectangular shape as shown in FIG. 6-2, the frame-shaped overlap region 9b having a width of 20 μm is provided in the outer peripheral portion of the opening 8a on the back surface insulating film 8, and the back-surface-aluminum-electrode material paste 9a is applied to a limited area on the back surface insulating film 8 by the screen printing method. For example, when the width w of the opening 8a is 100 μm, the back-surface-aluminum-electrode material paste 9a is printed in the shape of a substantially rectangular shape having a width of “100 μm+20 μm+20 μm=140 μm”.

Next, a light-receiving-surface-electrode material paste 5a, which is an electrode material of the light-receiving-surface-side electrode 5 and contains silver (Ag), glass, and the like, is selectively applied to the anti-reflective film 4 of the semiconductor substrate 1 in the shape of the light-receiving-surface-side electrode 5 by the screen printing method and the light-receiving-surface-electrode material paste 5a is dried (FIG. 5-7). As the light-receiving-surface-electrode material paste 5a, for example, a pattern of the elongated grid electrodes 6, which have a width of 80 μm to 150 μm and are arranged at intervals of 2 mm to 3 mm, and a pattern of the strip-shaped bus electrodes 7, which have a width of 1 mm to 3 mm and are arranged at intervals of 5 mm to 10 mm in a direction substantially orthogonal to the pattern of the grid electrodes 6, are printed. However, because the shape of the light-receiving-surface-side electrode 5 is not directly related to the present invention, it can be freely set while balancing the electrode resistance and the printing light shielding rate.

Thereafter, firing is performed, for example, at a peak temperature of 760° C. to 900° C. by using an infrared furnace heater. Consequently, the light-receiving-surface-side electrode 5 and the back surface aluminum electrodes 9 are formed and the Al—Si alloy portion 11 is formed in a region, which is on the back surface side of the semiconductor substrate 1 and is in contact with each back surface aluminum electrode 9, and is formed in a portion near the region. Moreover, in the outer peripheral portion thereof, the BSF layer 12, which is a p+ region in which aluminum is diffused at high concentration from the back surface aluminum electrode 9, is formed to surround the Al—Si alloy portion 11 and the BSF layer 12 and the back surface aluminum electrode 9 are electrically connected (FIG. 5-8). At the connection points, the recombination velocity at the interfaces degrades, however, the BSF layers 12 can nullify this effect. Moreover, silver in the light-receiving-surface-side electrode 5 penetrates the anti-reflective film 4, whereby the n-type impurity diffusion layer 3 and the light-receiving-surface-side electrode 5 are electrically connected.

At this time, because the region, to which the back-surface-aluminum-electrode material paste 9a is not applied, in the back surface of the semiconductor substrate 1 is protected by the back surface insulating film 8 that consists of a silicon nitride film (SiN film), the adhesion or fixation of contaminants to the back surface of the semiconductor substrate 1 does not proceed even during heating by firing, therefore, the recombination velocity does not degrade and favorable conditions can be maintained.

Next, a high reflective structure is formed on the back surface side of the semiconductor substrate 1. Specifically, a silver (Ag) film (silver sputtering film) is formed over the entire back surface of the semiconductor substrate 1 by the sputtering method as the back surface reflective film 10 so as to cover the back surface aluminum electrodes 9 and the back surface insulating film 8 (FIG. 5-9). The dense back surface reflective film 10 can be formed by forming the back surface reflective film 10 by the sputtering method, therefore, it is possible to form the back surface reflective film 10 that can realize higher light reflection than a silver (Ag) film formed by the printing method. The back surface reflective film 10 may be formed by the vapor deposition method. Moreover, in this embodiment, the back surface reflective film 10 is formed on the entire back surface of the semiconductor substrate 1, however, it is sufficient that the back surface reflective film 10 is formed to cover at least the back surface insulating film 8 on the back surface side of the semiconductor substrate 1.

Consequently, the solar cell according to the first embodiment illustrated in FIG. 1-1 to FIG. 1-3 is manufactured. The order of the application of the paste as the electrode material may be switched between the light receiving surface side and the back surface side.

As described above, in the manufacturing method of the solar cell according to the first embodiment, the back-surface-aluminum-electrode material paste 9a is applied after the back surface insulating film 8 having the openings 8a is formed on the back surface of the semiconductor substrate 1 and firing is performed, therefore, the region in which the back-surface-aluminum-electrode material paste 9a is not applied is protected by the back surface insulating film 8. Thus, the adhesion or fixation of contaminants to the back surface of the semiconductor substrate 1 does not proceed even during heating by firing, therefore, the recombination velocity does not degrade and favorable conditions can be maintained. Consequently, the photoelectric conversion efficiency can improve.

Moreover, in the manufacturing method of the solar cell according to the first embodiment, the back surface reflective film 10 is formed to cover at least the back surface insulating film 8 on the back surface of the semiconductor substrate 1. Therefore, the light transmitted through the semiconductor substrate 1 and the back surface insulating film 8 can be reflected by the back surface reflective film 10 and returned to the semiconductor substrate 1, whereby an excellent optical confinement effect can be obtained. Thus, the output characteristics can be improved and therefore a high photoelectric conversion efficiency can be realized.

Moreover, in the manufacturing method of the solar cell according to the first embodiment, the back surface reflective film 10 is formed by the sputtering method. The dense back surface reflective film 10 can be formed by forming the back surface reflective film 10 from the sputtering film instead of performing the printing method using electrode paste. Therefore, it is possible to form the back surface reflective film 10 that can realize higher light reflection than a film formed by the printing method, whereby an excellent optical confinement effect can be obtained.

Thus, according to the manufacturing method of the solar cell according to the first embodiment, the back surface structure having both a low recombination velocity and a high back surface reflectance can be obtained, therefore, it is possible to manufacture a solar cell which is excellent in long wavelength sensitivity and in which the photoelectric conversion efficiency is improved. Furthermore, because the photoelectric conversion efficiency of the solar cell can be improved, the semiconductor substrate 1 can be made thin and therefore the manufacturing cost can be reduced. Thus, the solar cell that is excellent in cell characteristics and has a high quality can be manufactured at low cost.

### Second Embodiment

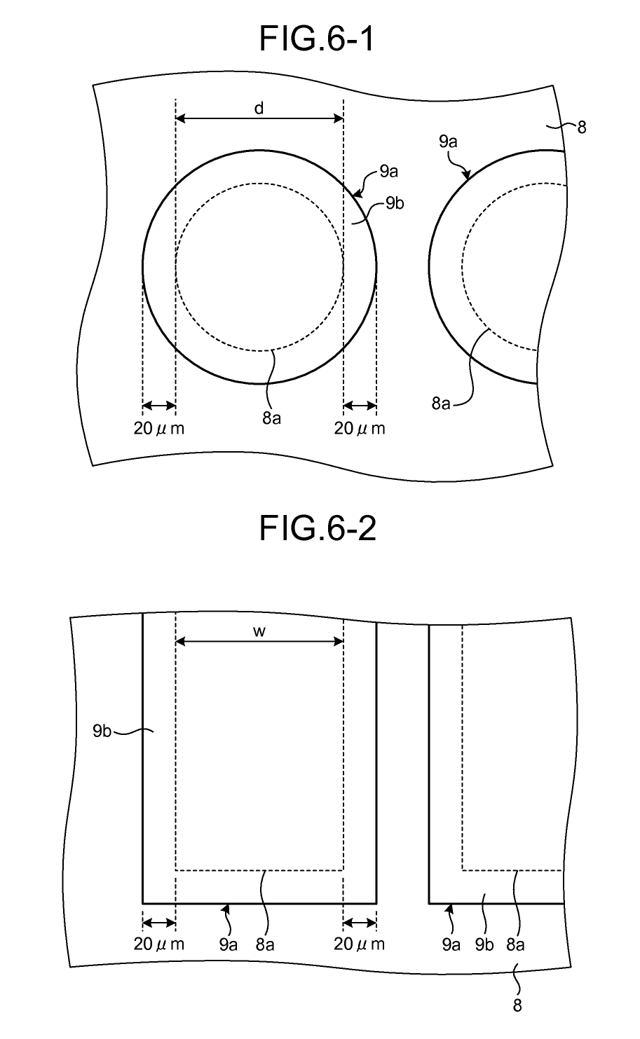

In the second embodiment, as another embodiment of the back surface reflective film 10, a case where the back surface reflective film 10 is made of metal foil is explained. FIG. 7 is a cross-sectional view of a main portion for explaining a cross-sectional structure of a solar cell according to the present embodiment, which is a diagram corresponding to FIG. 1-1. The solar cell according to the second embodiment is different from the solar cell according to the first embodiment in that the back surface reflective film is made of aluminum foil (aluminum foil) instead of a silver sputtering film. Other configurations are similar to the solar cell according to the first embodiment, therefore, a detailed explanation is thereof omitted.

As shown in FIG. 7, in the solar cell according to the present embodiment, a back surface reflective film 22 made of aluminum foil is attached by a conductive adhesive 21 arranged on the back surface aluminum electrodes 9 on the back surface of the semiconductor substrate 1 to cover the back surface aluminum electrodes 9 and the back surface insulating film 8, and the back surface reflective film 22 is electrically connected to the back surface aluminum electrodes 9 via the conductive adhesive 21. With such a configuration also, the light transmitted through the semiconductor substrate 1 and the back surface insulating film 8 can be reflected and returned to the semiconductor substrate 1 in a similar manner to the case of the first embodiment. Thus, an excellent optical confinement effect can be obtained with an inexpensive configuration.

In the present embodiment, the back surface reflective film 22 is made of aluminum foil that is metal foil. The back surface reflective film 22 is not a film formed by the printing method using electrode paste and is made of metal foil, therefore, the back surface reflective film 22 can realize higher light reflection than a metal film formed by the printing method. Thus, the light transmitted through the semiconductor substrate 1 and the back surface insulating film 8 can be reflected more efficiently and returned to the semiconductor substrate 1. Accordingly, the solar cell according to the present embodiment can obtain an excellent optical confinement effect in a similar manner to the case of the first embodiment by including the back surface reflective film 22 made of aluminum foil that is metal foil.

As a material of the back surface reflective film 22, a metal material that can be processed into foil can be used and, in a similar manner to the case of the back surface reflective film 10, it is preferable to use a metal material whose reflectance for the light having a wavelength of, for example, around 1100 nm is 90% or higher, preferably, 95% or higher. Consequently, it is possible to realize a solar cell that has a high long wavelength sensitivity and is excellent in optical confinement effect to the light in a long wavelength region. In other words, although it depends on the thickness of the semiconductor substrate 1, it is possible to realize a high generated current by efficiently introducing long wavelength light having a wavelength of 900 nm or longer, particularly, about 1000 nm to 1100 nm, into the semiconductor substrate 1, therefore, the output characteristics can be improved. As such a material, for example, silver (Ag) can be used other than aluminum (Al).

The solar cell according to the present embodiment configured as above can be manufactured by applying the conductive adhesive 21 to the back surface aluminum electrodes 9 after the processes explained with reference to FIG. 5-1 to FIG. 5-8 in the first embodiment and attaching the back surface reflective film 22 by the conductive adhesive 21 to cover the back surface aluminum electrodes 9 and the back surface insulating film 8. In this case also, it is sufficient that the back surface reflective film 22 is formed to cover at least the back surface insulating film 8 on the back surface side of the semiconductor substrate 1.

In the solar cell according to the second embodiment configured as above, an excellent suppression effect of the recombination velocity of carries can be obtained in the back surface of the semiconductor substrate 1 by including the silicon nitride film (SiN film) formed on the back surface of the semiconductor substrate 1 by the plasma CVD method as the back surface insulating film 8. Consequently, in the solar cell according to the present embodiment, the output characteristics can be improved and therefore a high photoelectric conversion efficiency can be realized.

Moreover, in the solar cell according to the second embodiment, higher light reflection than a metal film formed by a conventional printing method can be realized by including the back surface reflective film 22 that covers the back surface insulating film 8 and is made of aluminum foil that is metal foil, therefore, the light transmitted through the semiconductor substrate 1 and the back surface insulating film 8 can be reflected more and returned to the semiconductor substrate 1. Therefore, in the solar cell according to the present embodiment, an excellent optical confinement effect can be obtained. Thus, the output characteristics can be improved and therefore a high photoelectric conversion efficiency can be realized.

Accordingly, in the solar cell according to the second embodiment, a solar cell, which is excellent in long wavelength sensitivity and in which the photoelectric conversion efficiency is improved, can be realized by including a back surface structure that has both a low recombination velocity and a high back surface reflectance.

Moreover, in the manufacturing method of the solar cell according to the second embodiment, the back-surface-aluminum-electrode material paste 9a is applied after the back surface insulating film 8 having the openings 8a is formed on the back surface of the semiconductor substrate 1 and firing is performed, therefore, the region, to which the back-surface-aluminum-electrode material paste 9a is not applied, is protected by the back surface insulating film 8. Thus, the adhesion or fixation of contaminants to the back surface of the semiconductor substrate 1 does not proceed even during heating by firing, therefore, the recombination velocity does not degrade and favorable conditions can be maintained. Consequently, the photoelectric conversion efficiency improves.

Moreover, in the manufacturing method of the solar cell according to the second embodiment, the back surface reflective film 22 is formed to cover at least the back surface insulating film 8 on the back surface of the semiconductor substrate 1. Therefore, the light transmitted through the semiconductor substrate 1 and the back surface insulating film 8 can be reflected by the back surface reflective film 22 and returned to the semiconductor substrate 1, whereby an excellent optical confinement effect can be obtained. Thus, the output characteristics can be improved and therefore a high photoelectric conversion efficiency can be realized.

Moreover, in the manufacturing method of the solar cell according to the second embodiment, the back surface reflective film 22 is formed by attaching aluminum foil that is metal foil to the back surface aluminum electrodes 9. The dense back surface reflective film 22 can be formed by forming the back surface reflective film 22 from aluminum foil that is metal foil as the back surface reflective film 22 instead of performing the printing method using electrode paste. Therefore, it is possible to form the back surface reflective film 22 that can realize higher light reflection than a film formed by the printing method, whereby an excellent optical confinement effect can be obtained.

Thus, according to the manufacturing method of the solar cell according to the second embodiment, the back surface structure having both a low recombination velocity and a high back surface reflectance can be obtained, therefore, it is possible to manufacture a solar cell which is excellent in long wavelength sensitivity and in which the photoelectric conversion efficiency is improved. Furthermore, because the photoelectric conversion efficiency of the solar cell can be improved, the semiconductor substrate 1 can be made thin and therefore the manufacturing cost can be reduced. Thus, the solar cell that is excellent in cell characteristics and has a high quality can be manufactured at low cost.

In the above embodiment, a case of using a p-type silicon substrate as a semiconductor substrate is explained, however, an opposite conductivity-type solar cell, in which an n-type silicon substrate is used and a p-type diffusion layer is formed, may be formed. Moreover, a polycrystalline silicon substrate is used as a semiconductor substrate, however, a single-crystal semiconductor may be used. Moreover, in the above description, the substrate thickness of the semiconductor substrate is 200 μm, however, it is possible to use a semiconductor substrate that is thinned to about the substrate thickness with which the semiconductor substrate can hold itself, for example, about 50 μm. Furthermore, in the above description, the dimensions of the semiconductor substrate are 150 mm×150 mm, however, the dimensions of the semiconductor substrate are not limited thereto.

### Third Embodiment

In the third embodiment, an explanation is given of a back surface structure that includes a connecting electrode for connecting a metal tab, which connects cells when the solar cells are configured into a module, in the solar cell in the first embodiment and the second embodiment described above.

For improving the efficiency of a crystalline silicon solar cell, recently, suppression of the recombination velocity in the back surface is particularly becoming more important. It is not uncommon that the carrier diffusion length exceeds the thickness of the silicon substrate in both a single-crystal silicon solar cell and a polycrystalline silicon solar cell. Therefore, the magnitude of the surface recombination velocity in the back surface of the silicon substrate greatly affects the characteristics of the solar cell.

On the other hand, when solar cells, each of which is a device unit, are configured into a solar cell module that is an actual product, a plurality of solar cells is connected in series or both in series and in parallel via metal tabs. In a specific method of configuring solar cells into a solar cell module in this manner, metal paste containing silver is often used as the material of the connecting electrode provided on the cell side.

This is largely due to the characteristics of the fire through as well as in terms of cost. In the fire through, as a result of application and firing of the paste, silver, glass component, and the like contained in the paste interact with the silicon and eat into the silicon crystal and therefore both the electrical connection and the physical adhesion strength are obtained between the silicon substrate and the electrode.

This phenomenon occurs in a similar manner in silicon compound, such as a silicon nitride film (SiN film). When the metal paste is directly applied to the silicon nitride film (SiN film) and is fired, silver, glass component, and the like contained in the paste penetrate the silicon nitride film (SiN film) by eating into the silicon nitride film, therefore, the electrode and the silicon crystal can be connected without performing patterning. Thus, the fire through greatly contributes to simplification of the solar cell manufacturing process. The fire through is performed also in the processes illustrated in FIGS. 5-7 and FIGS. 5-8 in the first embodiment.

However, at the interface between the silver electrode and the silicon, the recombination velocity is extremely high. Therefore, in the back surface of the silicon solar cell, formation of the electrode by the fire through becomes a major problem. Specially, the open circuit voltage (Voc) decreases significantly in some cases even with slight contact between the back surface silver electrode and the silicon substrate. In other words, the open circuit voltage (Voc) and the photoelectric conversion efficiency decrease in some cases by electrically connecting the back surface silver electrode and the silicon crystal of the silicon substrate in the back surface structure of the silicon solar cell. Therefore, in the back surface structure of the silicon solar cell, it is preferable to suppress the effect of the electrical connection between the back surface silver electrode and the silicon substrate while ensuring the physical adhesion strength between the back surface silver electrode and the back surface side of the silicon substrate.

In the following, as a method for solving such a problem, an explanation is given of a structure, which suppresses the effect of the electrical connection between the back surface silver electrode and the silicon crystal even if penetration of the back surface silver electrode by the fire through reaches the silicon (Si) crystal in the back surface of the silicon substrate and therefore practically causes no problem. A specific embodiment includes providing a limit on the area ratio and the shape of the back surface silver electrode.

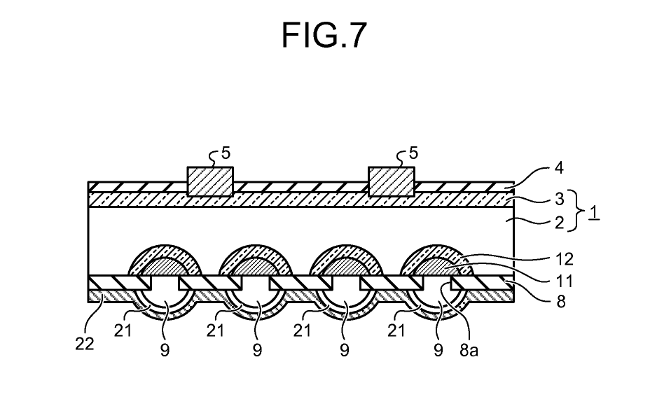

FIG. 8-1 to FIG. 8-3 are diagrams illustrating a configuration of a solar cell that is a photovoltaic device according to the third embodiment, in which FIG. 8-1 is a cross-sectional view of a main portion for explaining a cross-sectional structure of the solar cell, FIG. 8-2 is a top view of the solar cell when viewed from a light receiving surface side, and FIG. 8-3 is a bottom view of the solar cell when viewed from the opposite side (back surface side) of the light receiving surface side. FIG. 8-1 is a cross-sectional view of a main portion taken along line B-B in FIG. 8-2.

The solar cell according to the third embodiment is different from the solar cell according to the first embodiment in that a back surface silver electrode 31, which is mainly made of silver (Ag), is included on the back surface side of the semiconductor substrate 1. In other words, the solar cell according to the third embodiment includes the back surface aluminum electrodes 9, which are mainly made of aluminum (Al), and the back surface silver electrode 31, which is mainly made of silver (Ag), as the back surface side electrodes on the back surface side of the semiconductor substrate 1. Other configurations are similar to the solar cell according to the first embodiment, therefore, a detailed explanation is thereof omitted.

A metal tab, which connects the cells when the solar cells are configured into a module, is connected to the back surface silver electrode 31. For example, two back surface silver electrodes 31 are provided to extend in a direction substantially parallel to the extending direction of the bus electrodes 7 in a region between the adjacent back surface aluminum electrodes 9 on the back surface side of the semiconductor substrate 1. Moreover, the back surface silver electrodes 31 project from the surface of the back surface reflective film 10 and penetrate the back surface insulating film 8 such that at least part thereof is physically and electrically connected to the back surface of the semiconductor substrate 1. The width of the back surface silver electrodes 31 is set to, for example, a dimension substantially equal to that of the bus electrodes 7.

As the connecting electrode material of the silicon solar cell, typically, silver paste is used, and for example, lead-boron glass is added thereto. This glass is fritted, and includes a composition of, for example, lead (Pb), boron (B), silicon (Si), and oxygen (O), and, furthermore, zinc (Zn), cadmium (Cd), or the like is also mixed in some cases. The back surface silver electrodes 31 are formed by the fire through by applying and firing such silver paste.

The back surface silver electrodes 31 as above can be manufactured by the fire through by applying silver paste that is electrode material paste to the region on the back surface insulating film 8 in the shape of the back surface silver electrodes 31 by the screen printing and drying it in the process in FIG. 5-7 in the first embodiment and then firing it in the process in FIG. 5-8. For other processes, the processes in FIG. 5-1 to FIG. 5-9 are performed in a similar manner to the case of the first embodiment, whereby the solar cell according to the third embodiment can be manufactured.

Next, the difference in the open circuit voltage (Voc) of the silicon solar cell depending on the shape of the back surface silver electrodes 31 will be explained. First, solar cells of a sample D to a sample F having a structure shown in FIG. 8-1 to FIG. 8-3 are manufactured by using the p-type polycrystalline silicon substrate 2 of 15 cm². Moreover, a solar cell of a sample G is manufactured as a target for comparison in a similar manner to the sample D to the sample F except that the back surface silver electrodes 31 are not formed. The pattern (printing pattern of silver paste) of the back surface silver electrodes of each sample is manufactured under the following conditions.

(Sample D): width 100 μm×length 148 mm×75 pieces (2 mm interval)

(Sample E): width 3.5 mm×length 148 mm×2 pieces (75 mm interval)

(Sample F): width 7.5 mm×length 10 mm×7 places×2 lines (75 mm interval)

(Sample G): no back Ag paste printing (reference: comparison target)

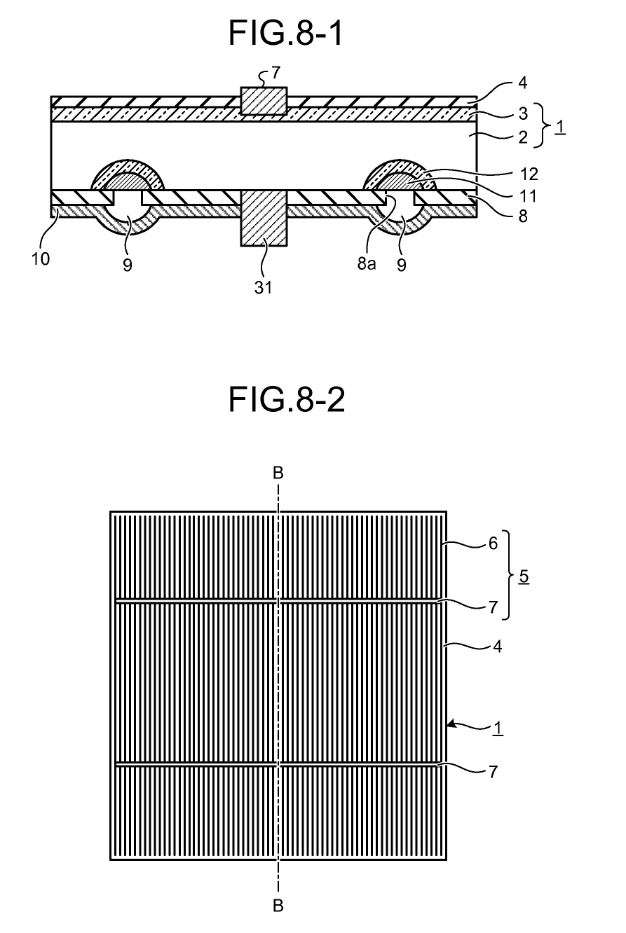

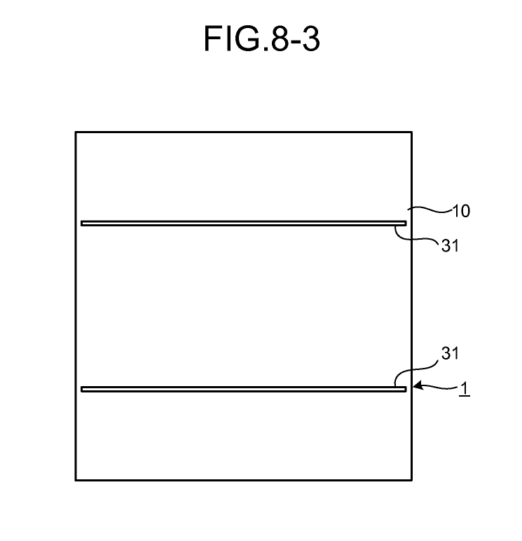

FIG. 9 is a characteristic diagram illustrating the open circuit voltage (Voc) of the solar cells of the sample D to the sample F. FIG. 10 is a diagram illustrating the electrode area ratio of the back surface silver electrodes 31 in the solar cells of the sample D to the sample F. The electrode area ratio is the ratio of the area of the back surface silver electrodes 31 to the area of the back surface of the p-type polycrystalline silicon substrate 2. Moreover, as the area of the back surface silver electrodes 31, the printed area of the silver paste when the back surface silver electrodes 31 are formed is used. It can be found from FIG. 9 that the open circuit voltage (Voc) of the sample D is greatly lower than other samples among the four kinds of samples described above. On the other hand, it can be found from FIG. 10 that the electrode area ratio in any of the solar cells of the sample D to the sample F is approximately equal to 4.6% to 4.7%. Therefore, the difference of the open circuit voltage (Voc) in FIG. 9 cannot be explained only from the difference of the area ratio of the back surface silver electrodes 31. Thus, as will be described below, the relationship between the shape of the back surface silver electrodes 31 and the diffusion length can be important.

The structure of the solar cell according to the third embodiment is for obtaining a high efficiency, therefore, a large diffusion length of a single-crystal or polycrystalline silicon to be used is used as a practical precondition. In order to effectively obtain the effect of obtaining a high efficiency, it is required that the diffusion length is at least 300 μm or longer, desirably, 500 μm or longer. In the following, a case where the diffusion length is, for example, 500 μm is explained as an example.

As explained above, the effect of the back surface silver electrodes 31 on the open circuit voltage (Voc) depends on the magnitude of the recombination velocity at its interface. In this embodiment, “affected” means that generated carriers are diffused and recombined at the interface earlier than bulk recombination of the semiconductor material itself of the solar cell substrate. Therefore, the affected range is not infinite and is closely associated with the distance in which the generated carriers can be diffused, i.e., the diffusion length.

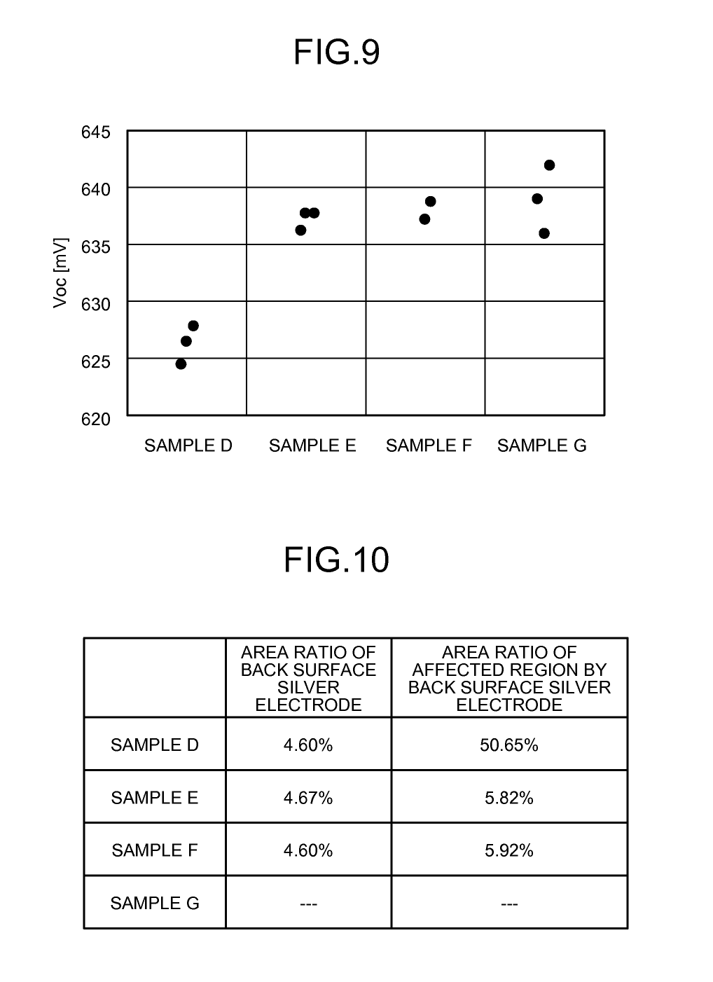

FIG. 10 also illustrates a calculation result of the area ratio of the “affected regions by the back surface silver electrodes 31” that include peripheral regions, which are obtained by extending the patterns of the back surface silver electrodes 31 outward by the diffusion length: 500 μm for each sample in the back surface of the p-type polycrystalline silicon substrate 2. The area ratio is the ratio of the area of the affected regions by the back surface silver electrodes 31 to the area of the back surface of the p-type polycrystalline silicon substrate 2. FIG. 11 is a plan view schematically illustrating the affected region by the back surface silver electrode 31. FIG. 11 illustrates the back surface reflective film 10 in a transparent manner. Although FIG. 11 is a plan view, hatching is applied to improve drawing legibility. As shown in FIG. 11, the affected region by the back surface silver electrode 31 includes the pattern region of the back surface silver electrode 31 and a peripheral region 32. The peripheral region 32 is part of the region, in which the back surface insulating film 8 is formed, in the back surface of the p-type polycrystalline silicon substrate 2.

As is apparent from FIG. 10, the area ratio of the affected regions by the back surface silver electrodes 31 in the sample E and the sample F is about 5% and more than 5%. On the other hand, the area ratio of the affected regions by the back surface silver electrodes 31 in the sample D exceeds 50%. On the basis of this result and the result in FIG. 9, it can be said that when the area ratio of the affected regions by the back surface silver electrodes 31 to the area of the back surface of the p-type polycrystalline silicon substrate 2 is large, the open circuit voltage (Voc) decreases. This result indicates that in order to keep the open circuit voltage (Voc) high, it is important to suppress not only the area ratio of the patterns itself of the back surface silver electrodes 31 but also the area ratio of the range affected by the patterns.

In the back surface of the p-type polycrystalline silicon substrate 2, when both the region (high open circuit voltage region) in which the open circuit voltage (Voc) is high, i.e., the highly passivated region in the back surface of the p-type polycrystalline silicon substrate 2, and the region (low open circuit voltage region) in which the open circuit voltage (Voc) is low, i.e., the region that is greatly affected by the back surface silver electrodes 31 in the back surface of the p-type polycrystalline silicon substrate 2, are present, the total open circuit voltage (Voc) can be considered based on the parallel connection.

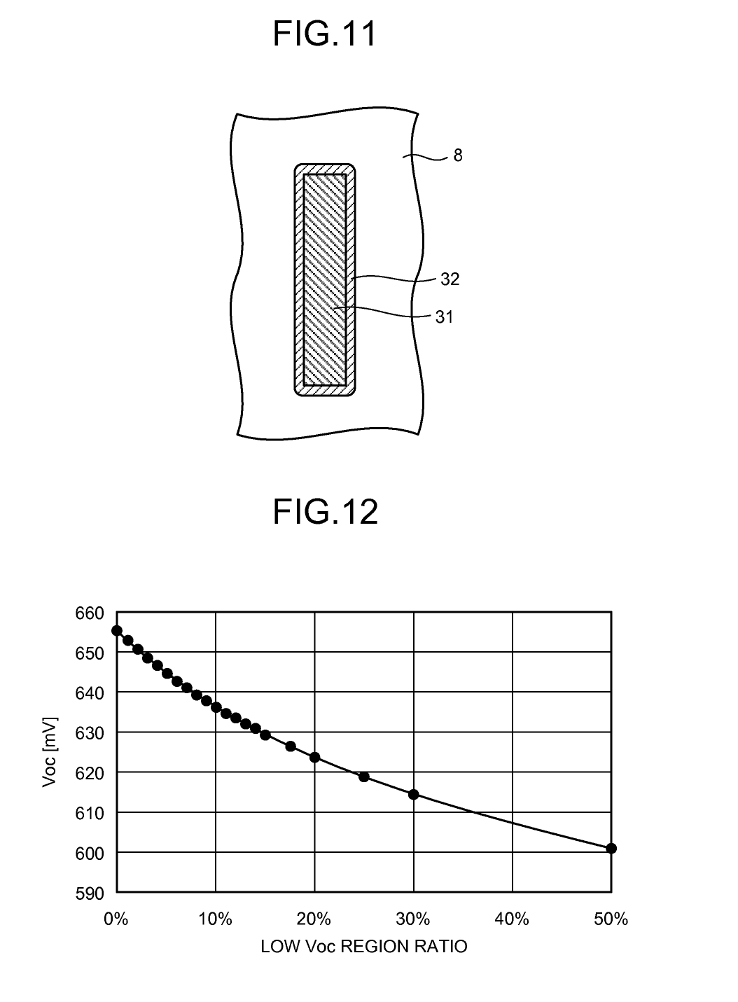

FIG. 12 is a characteristic diagram illustrating an example of a relationship between the ratio of the low open circuit voltage region in the back surface of the silicon substrate and the open circuit voltage (Voc). In FIG. 12, for example, the voltage in the high open circuit voltage region is temporarily fixed to 655 mV and the voltage in the low open circuit voltage region is temporarily fixed to 580 mV, and change in the total open circuit voltage (Voc) on the basis of the ratio between both of them is calculated. Because the total open circuit voltage (Voc) is based on the parallel connection as described above and the relationship between current and voltage in a diode is based on the exponential function, even if the ratio of the low open circuit voltage region is small, the effect on the total open circuit voltage (Voc) is not small.

In order to improve the efficiency of the solar cell according to the present embodiment, the open circuit voltage (Voc) is required to be at least 635 mV or more, desirably, 640 mV or more. Therefore, the upper limit of the area ratio of the low open circuit voltage region is required to be at most 10% or less, desirably, 8% or less with reference to FIG. 12.

On the other hand, the original main function of the back surface silver electrode 31 is to be directly connected to the metal tab when tab connection is performed, therefore, it is preferable to have the area ratio of about 3% or more to ensure the adhesive property thereof. Moreover, because the back surface silver electrode 31 is interconnected with other adjacent cells, it is desirable that a continuous or intermittent linear, strip-shaped, or rectangular portion occupies an area equal to or more than half of that of the back surface silver electrode 31.

Moreover, in terms of the thickness of the back surface insulating film 8 that consists of a silicon nitride film (SiN film) formed on the back surface of the p-type polycrystalline silicon substrate 2, the film thickness of 60 nm or more is required to obtain the sufficient suppression effect of the surface recombination velocity on the back surface side. On the other hand, when the thickness of the back surface insulating film 8 is 160 nm or more, the fire through that occurs when the back surface silver electrodes 31 are formed becomes difficult to reach the back surface of the p-type polycrystalline silicon substrate 2. When the thickness of the back surface insulating film 8 is 240 nm or more, the fire through does not reach the back surface of the p-type polycrystalline silicon substrate 2 at all. Therefore, when the film thickness is 240 nm or more, at least 160 nm or more, the need for modification itself of the present invention does not arise. The thick film thickness of course inhibits productivity, therefore, the upper limit of the thickness of the back surface insulating film 8 according to the present embodiment is set to 160 nm or less, at most 240 nm or less.

In the solar cell according to the third embodiment configured as above, an excellent suppression effect of the recombination velocity of carriers can be obtained in the back surface of the semiconductor substrate 1 by including the silicon nitride film (SiN film) formed on the back surface of the semiconductor substrate 1 by the plasma CVD method as the back surface insulating film 8. Consequently, in the solar cell according to the present embodiment, the output characteristics can be improved and therefore a high photoelectric conversion efficiency can be realized.

Moreover, in the solar cell according to the third embodiment, higher light reflection than a silver (Ag) film formed by a conventional printing method can be realized by including the back surface reflective film 10 that covers the back surface insulating film 8 and consists of a silver sputtering film, therefore, the light transmitted through the semiconductor substrate 1 and the back surface insulating film 8 can be reflected more effectively and returned to the semiconductor substrate 1. Therefore, in the solar cell according to the present embodiment, an excellent optical confinement effect can be obtained. Thus, the output characteristics can be improved and therefore a high photoelectric conversion efficiency can be realized.

Moreover, in the solar cell according to the third embodiment, the ratio of the area of the affected regions by the back surface silver electrodes 31 to the area of the back surface of the p-type polycrystalline silicon substrate 2 is 10% or less, desirably, 8% or less. Consequently, even if penetration of the back surface silver electrodes 31 by the fire through reaches the silicon (Si) crystal in the back surface of the p-type polycrystalline silicon substrate 2, the effect of the electrical connection between the back surface silver electrodes 31 and the silicon crystal is suppressed, therefore, the open circuit voltage (Voc) and the photoelectric conversion efficiency can be prevented from decreasing. In other words, it is possible to suppress a decrease in the open circuit voltage (Voc) and the photoelectric conversion efficiency due to the electrical connection between the back surface silver electrodes 31 and the silicon crystal in the back surface of the p-type polycrystalline silicon substrate 2 while ensuring the physical adhesion strength between the back surface of the p-type polycrystalline silicon substrate 2 and the back surface silver electrodes 31.

Therefore, in the solar cell according to the third embodiment, a solar cell can be realized, which has a back surface structure that has both a low recombination velocity and a high back surface reflectance, which is excellent in long wavelength sensitivity and the open circuit voltage (Voc), and in which the photoelectric conversion efficiency is improved.

The present embodiment may be applied also to the structure in the second embodiment. In this case also, the effect similar to the above can be obtained.

### INDUSTRIAL APPLICABILITY

As described above, the photovoltaic device according to the present invention is useful for realizing a highly-efficient photovoltaic device by a low recombination velocity and a high back surface reflectance.

### REFERENCE SIGNS LIST

1 semiconductor substrate
1a p-type polycrystalline silicon substrate
2 p-type polycrystalline silicon substrate
3 n-type impurity diffusion layer
4 anti-reflective film
5 light-receiving-surface-side electrode
5a light-receiving-surface-electrode material paste
6 grid electrode
7 bus electrode
8 back surface insulating film
8a opening
9 back surface aluminum electrode
9a back-surface-aluminum-electrode material paste
9b overlap region
10 back surface reflective film
11 aluminum-silicon (Al—Si) alloy portion
12 BSF layer
21 conductive adhesive
22 back surface reflective film
31 back surface silver electrode
32 peripheral region

1-22. (canceled)

23. A photovoltaic device comprising:
a first conductivity-type semiconductor substrate that includes an impurity diffusion layer in which a second conductivity-type impurity element is diffused on one surface side;
an anti-reflective film formed on the impurity diffusion layer;
a first electrode that penetrates the anti-reflective film and is electrically connected to the impurity diffusion layer;
a back surface insulating film that includes a plurality of openings that reach an other surface side of the semiconductor substrate and is formed on the other surface side of the semiconductor substrate;
a second electrode that is formed on the other surface side of the semiconductor substrate; and
a back surface reflective film that is formed to cover at least the back surface insulating film and is made of metal, wherein
the second electrode includes an aluminum-based electrode that is made of a material including aluminum and is connected to the other surface side of the semiconductor substrate by being embedded in at least the openings on the other surface side of the semiconductor substrate, and a silver-based electrode that is made of a material including silver, that is provided in a region between the openings on the other surface side of the semiconductor substrate, that is electrically connected to the other surface side of the semiconductor substrate by at least a part thereof penetrating the back surface insulating film, and that is electrically connected to the aluminum-based electrode via the back surface reflective film, and
a sum of an area of the silver-based electrode in a plane of the semiconductor substrate and an area of a peripheral region, which is obtained by extending a pattern of the silver-based electrode by a diffusion length of a carrier in the semiconductor substrate outward in a plane of the semiconductor substrate, is 10% or less of an area on the other surface side of the semiconductor substrate.

24. The photovoltaic device according to claim 23, wherein
the back surface reflective film is made of a metal film formed by a vapor phase growth method.

25. The photovoltaic device according to claim 23, wherein
the back surface reflective film is configured to include a metal foil.

26. The photovoltaic device according to claim 23, wherein
the sum of the area of the silver-based electrode and the area of the peripheral region is 8% or less of the area of the other surface side of the semiconductor substrate.

27. The photovoltaic device according to claim 23, wherein
the semiconductor substrate is a silicon substrate, and
the diffusion length is 500 μm or longer.

28. The photovoltaic device according to claim 23, wherein
the semiconductor substrate is a silicon substrate, and
the diffusion length is 300 μm or longer.

29. The photovoltaic device according to claim 23, wherein
the back surface insulating film is a silicon nitride film formed by a plasma CVD method.

30. The photovoltaic device according to claim 23, wherein
the back surface insulating film is a laminated film in which a silicon oxide film formed by a thermal oxidation and a silicon nitride film formed by a plasma CVD method are laminated on the other surface side of the semiconductor substrate.

31. The photovoltaic device according to claim 30, wherein
the silicon oxide film has a thickness of 10 nm or more and 50 nm or less.

32. The photovoltaic device according to claim 29, wherein
the silicon nitride film has a refractive index of 1.9 or more and 2.2 or less and a thickness of 60 nm or more and less than 240 nm.

33. The photovoltaic device according to claim 29, wherein
the silicon nitride film has a refractive index of 1.9 or more and 2.2 or less and a thickness of 60 nm or more and less than 160 nm.

34. The photovoltaic device according to claim 23, wherein
the openings have a substantially circular dot shape or a substantially rectangular shape in which a diameter or a width is 20 μm to 200 μm and an interval between adjacent openings is 0.5 mm to 2 mm.

35. The photovoltaic device according to claim 23, wherein
the openings have a stripe shape in which a width is 20 μm to 200 μm and an interval between adjacent openings is 0.5 mm to 3 mm.

36. The photovoltaic device according to claim 34, wherein
the aluminum-based electrode is formed to be embedded in the openings and overlap the back surface insulating film.

37. The photovoltaic device according to claim 36, wherein
the aluminum-based electrode is formed to overlap the back surface insulating film by a width of 10 μm to 50 μm from an end portion of the openings.

38. The photovoltaic device according to claim 23, wherein
the back surface reflective film is configured to include a metal foil, and
the metal foil is an aluminum foil.

39. The photovoltaic device according to claim 23, wherein
the back surface reflective film is configured to include a metal foil, and
the metal foil is attached to the aluminum-based electrode by a conductive adhesive and is electrically connected to the aluminum-based electrode via the conductive adhesive.

40. The photovoltaic device according to claim 23, wherein
the back surface reflective film is made of a metal film formed by a vapor phase growth method, and
the metal film formed by a vapor phase growth method is a metal sputtering film or a vapor deposited film.

41. A manufacturing method of a photovoltaic device comprising:
a first step of forming an impurity diffusion layer in which a second conductivity-type impurity element is diffused on one surface side of a first conductivity-type semiconductor substrate;
a second step of forming an anti-reflective film on the impurity diffusion layer;
a third step of forming a back surface insulating film on an other surface side of the semiconductor substrate;
a fourth step of forming a plurality of openings that reach the other surface side of the semiconductor substrate in at least part of the back surface insulating film;
a fifth step of applying a first electrode material to the anti-reflective film;
a sixth step of applying a first second-electrode material including aluminum to the other surface side of the semiconductor substrate to fill at least the openings;
a seventh step of applying a second second-electrode material including silver to the back surface insulating film;
an eighth step of forming a first electrode and a second electrode by firing the first electrode material, the first second-electrode material, and the second second-electrode material, the first electrode penetrating the anti-reflective film, the first electrode being electrically connected to the impurity diffusion layer, the second electrode including an aluminum-based electrode and a silver-based electrode, the aluminum-based electrode including aluminum, the aluminum-based electrode being electrically connected to the other surface side of the semiconductor substrate by being embedded in at least the openings on the other surface side of the semiconductor substrate, the silver-based electrode including silver, the silver-based electrode being provided in a region between the openings on the other surface side of the semiconductor substrate, the silver-based electrode being electrically connected to the other surface side of the semiconductor substrate by at least a part thereof penetrating the back surface insulating film; and
a ninth step of forming a back surface reflective film made of metal to cover at least the back surface insulating film such that the aluminum-based electrode and the silver-based electrode are electrically connected, wherein
a sum of an application area of the second second-electrode material in a plane of the semiconductor substrate and an area of a peripheral region, which is obtained by extending an application pattern of the second second-electrode material by a diffusion length of a carrier in the semiconductor substrate outward in a plane of the semiconductor substrate, is 10% or less of an area on the other surface side of the semiconductor substrate.

42. The manufacturing method of a photovoltaic device according to claim 41, wherein
the ninth step includes forming the back surface reflective film made of a metal film formed by a vapor phase growth method.

43. The manufacturing method of a photovoltaic device according to claim 41, wherein
the ninth step includes forming the back surface reflective film configured to include a metal foil.

44. The manufacturing method of a photovoltaic device according to claim 41, wherein
the third step includes forming a silicon nitride film as the back surface insulating film by a plasma CVD method.

45. The manufacturing method of a photovoltaic device according to claim 41, wherein
the third step includes forming a silicon oxide film as the back surface insulating film by a thermal oxidation on the other surface side of the semiconductor substrate and further includes forming a silicon nitride film on the silicon oxide film by a plasma CVD method.

46. The manufacturing method of a photovoltaic device according to claim 41, wherein
the sixth step includes applying the first second-electrode material to fill the openings and overlap the back surface insulating film by a width of 10 μm to 50 μm from an end portion of the openings.

47. The manufacturing method of a photovoltaic device according to claim 41, wherein
the ninth step includes forming the back surface reflective film configured to include a metal foil, and
the metal foil is an aluminum foil.

48. The manufacturing method of a photovoltaic device according to claim 41, wherein
the ninth step includes forming the back surface reflective film made of a metal film formed by a vapor phase growth method, and
the metal film formed by a vapor phase growth method is a metal sputtering film or a vapor deposited film.
